(19) United States
(12) Patent Application Publication
(10) Pub. No.: US 2026/0262158 A1
(43) Pub. Date: Sep. 3, 2026

(54) SUBSTRATE STRUCTURE AND POWER SUPPLY DEVICE

(71) Applicant: TDK CORPORATION, Tokyo (JP)

(72) Inventors: Norikazu SHIMIZU, Tokyo (JP); Masahide OHNISHI, Tokyo (JP)

(73) Assignee: TDK CORPORATION, Tokyo (JP)

(21) Appl. No.: 18/832,626

(22) PCT Filed: Nov. 1, 2023
(86) PCT No.: PCT/JP2023/039515

§ 371 Date: Jul. 24, 2024

(51) Int. Cl. H05K 1/02; H02M 3/335; H05K 3/28

(52) U.S. Cl. CPC H05K 1/0209; H05K 1/0256; H05K 3/28; H02M 3/33573; H02M 3/33592; H05K 2201/0175; H05K 2201/0769

(57) ABSTRACT

A substrate structure includes a substrate, a pair of conductor patterns formed on the main surface of the substrate and arranged spaced apart from each other, and a resist layer covering the main surface of the substrate. In at least part of a region between the pair of conductor patterns, a coating layer having higher adhesiveness than the resist layer covers the substrate with the coating layer being in contact with the substrate.

### TECHNICAL FIELD

The present disclosure relates to a substrate structure and a power supply device.

### BACKGROUND ART

Conventionally, a power supply device having an electronic substrate provided with a DC-to-DC converter circuit has been known (e.g., Patent Literature 1). The electronic substrate provided with the DC-to-DC converter circuit has a surface formed with a resist layer.

### CITATION LIST

### Patent Literature

Patent Literature 1: Japanese Unexamined Patent Publication No. 2001-24344

### SUMMARY OF INVENTION

### Technical Problem

Herein, in the case where the power supply device is used in the vehicle's engine room, the electronic substrate is exposed to high temperature and humidity conditions. Under these circumstances, there is a possibility for the resist layer to peel off from the substrate. On the other hand, in some cases, the substrate may be designed such that a pair of conductor patterns exhibiting a significant voltage difference are formed side by side. If the resist layer peels off between the pair of conductor patterns, a challenge arises where ionized metal migrates along the surface of the substrate, leading to the phenomenon of migration.

Thus, the present disclosure is intended to provide a substrate structure and a power supply device, capable of suppressing migration.

### Solution to Problem

A substrate structure according to one aspect of the present disclosure includes a substrate, a pair of conductor patterns formed on a main surface of the substrate and arranged spaced apart from each other, and a resist layer covering the main surface of the substrate. In at least part of a region between the pair of conductor patterns, a coating layer having higher adhesiveness than the resist layer covers the substrate with the coating layer being in contact with the substrate.

The substrate structure, according to one aspect of the present disclosure, includes the pair of conductor patterns formed on the main surface of the substrate, arranged spaced apart from each other. Additionally, in at least part of the region between the pair of conductor patterns, a coating layer that has higher adhesiveness than the resist layer covers the substrate while being in contact with the substrate. According to this structure, the high adhesiveness of the coating layer in contact with the substrate makes it possible to ensure insulation properties in the region between the pair of conductor patterns even if the resist layer peels off from the main surface of the substrate. Thus, it is possible to suppress migration between the pair of conductor patterns. As described above, migration can be suppressed.

The resist layer may be formed with an opening that opens to at least part of the region and to the conductor pattern, and the coating layer may be formed in the opening. In this case, it is possible for the coating layer to give a wider range of protection, including the vicinity of the conductor pattern.

The resist layer may cover the conductor pattern, the resist layer may be formed with an opening that opens to at least part of the region, and the coating layer may be formed in the opening. In this case, compared to the case where the conductor pattern is covered with the coating layer, it is possible to reduce the amount of the coating layer to be used.

The resist layer may be formed with a first opening that opens at a position on one of the conductor patterns in the region and a second opening that opens at a position on the other of the conductor patterns in the region. The resist layer may remain between the first opening and the second opening, and the coating layer may be formed in the first opening and the second opening. In this case, allowing the resist layer to remain makes it possible to suppress the adhesion of solder or the like to the main surface of the substrate.

In the region between the pair of conductor patterns, the main surface of the substrate may have a planar shape being continuous from the one conductor pattern to the other conductor pattern. Even without forming a slit in the substrate, the occurrence of migration can be suppressed by the coating layer.

The resist layer may be formed with an opening that opens to at least part of the region, and the coating layer may cover the resist layer at an edge portion of the opening. In this case, it is possible to improve the adhesiveness at the boundary between the resist layer and the coating layer.

The one conductor pattern and the other conductor pattern may extend parallel to each other. In this case, the distance between the conductor patterns remains constant, thus a similar insulation structure is applicable in the extending direction of the conductor patterns.

A power supply device according to one aspect of the present disclosure may have the above-described substrate structure.

According to this power supply device, it is possible to obtain similar operations and effects as the above-mentioned substrate structure.

### Advantageous Effects of Invention

According to one aspect of the present disclosure, it is possible to provide a substrate structure and a power supply device, capable of suppressing migration.

### BRIEF DESCRIPTION OF DRAWINGS

FIG. 1 illustrates a power supply device according to an embodiment of the present disclosure.

FIG. 2 is a circuit diagram illustrating a DC-to-DC converter circuit according to an embodiment of the present disclosure.

FIG. 3(a) is a plan view of a substrate structure, and FIG. 3(b) is a sectional view taken along the line IIIb-IIIb in FIG. 3(a).

FIG. 4 is an enlarged view illustrating the structure near an end portion of a coating layer in the width direction.

FIG. 5 is a diagram illustrating a method of manufacturing a substrate structure.

FIG. 6 is a diagram illustrating a substrate structure according to a comparative example.

FIG. 7 is a diagram illustrating a substrate structure according to a comparative example.

FIG. 8(a) and 8(b) illustrate a substrate structure according to a comparative example, and FIG. 8(c) illustrates a substrate structure according to a modification.

FIG. 9 is a diagram illustrating a substrate structure according to a modification.

FIG. 10 is a diagram illustrating a substrate structure according to a modification.

FIG. 11 is a diagram illustrating a substrate structure according to a modification.

FIG. 12 is a diagram illustrating a substrate structure according to a modification.

FIG. 13 is a diagram illustrating a substrate structure according to a modification.

FIG. 14 is a diagram illustrating a substrate structure according to a modification.

FIG. 15 is a diagram illustrating a substrate structure according to a modification.

FIG. 16 is a diagram illustrating a substrate structure according to a modification.

FIG. 17 is a diagram illustrating a substrate structure according to a modification.

### DESCRIPTION OF EMBODIMENTS

The following describes in detail several embodiments of the present disclosure. However, the present disclosure is not limited to the embodiments described below.

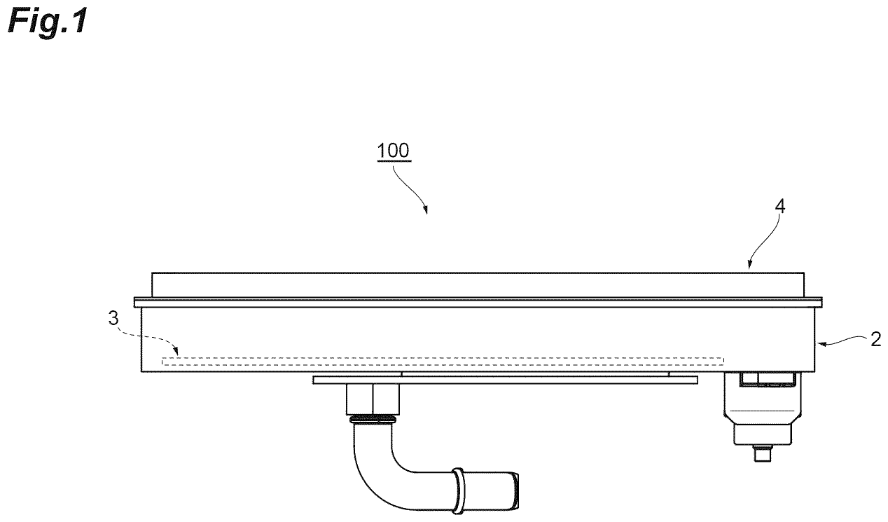

Referring to FIG. 1, a power supply device 100 including a substrate structure according to an embodiment of the present disclosure is described. FIG. 1 illustrates the power supply device 100 according to an embodiment of the present disclosure.

As illustrated in FIG. 1, the power supply device 100 is constructed by assembling a lid 4 onto a housing member 2 in which an electronic substrate 3 is accommodated. The power supply device 100 is, for example, a unit such as a DC-to-DC converter. The electronic substrate 3 includes a DC-to-DC converter circuit. This power supply device 100 is intended for use in environments such as the engine room of an automobile, where it may be subjected to high temperature and high humidity conditions.

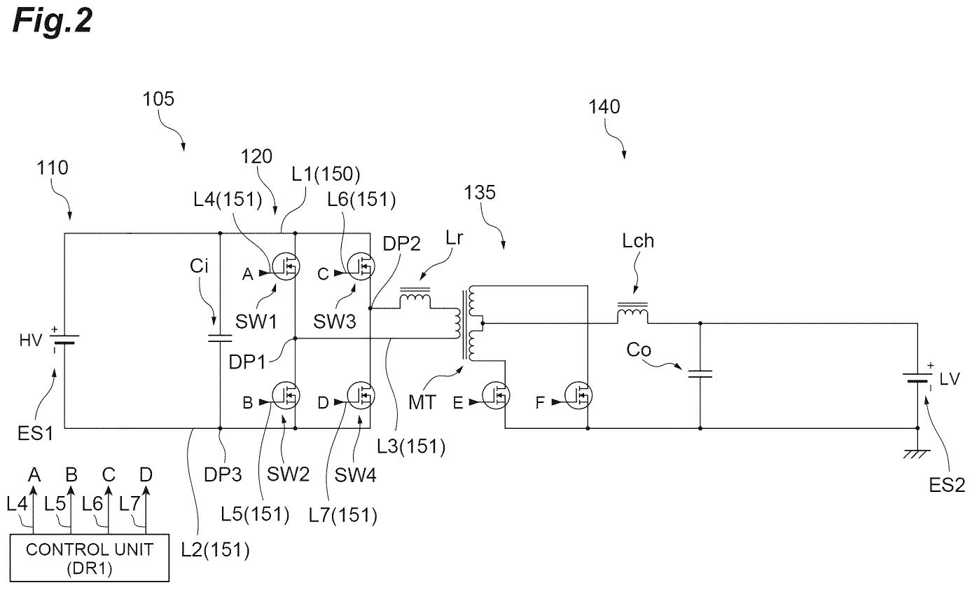

An example of the DC-to-DC converter circuit having a substrate structure 1 according to the present embodiment is now described. FIG. 2 is a circuit diagram illustrating the DC-to-DC converter circuit 105 according to the embodiment of the present disclosure. As illustrated in FIG. 2, the DC-to-DC converter circuit 105 includes a DC power supply circuit 110, an inverter circuit 120, and a DC voltage supply unit 140.

The DC power supply circuit 110 includes a smoothing capacitor Ci connected to a power supply ES1. The inverter circuit 120 is a circuit that converts DC voltage into high-frequency AC voltage. The inverter circuit 120 forms a bridge constituted by a first switching element SW1 and a third switching element SW3, a fourth switching element SW4, and a second switching element SW2, and in this configuration, the first switching element SW1 and the third switching element SW3 are connected to the positive output of the DC power supply circuit 110, and the fourth switching element SW4 and the second switching element SW2 face the first switching element SW1 and the third switching element SW3, respectively. There are provided a branching point DP1 between the first switching element SW1 and the second switching element SW2 and a branching point DP2 between the third switching element SW3 and the fourth switching element SW4, and these branching points DP1 and DP2 are connected to a main transformer MT via a reactor Lr and a reactor Lr, respectively. Moreover, a control unit DR1 is provided outside the power circuit system. The control unit DR1 is connected to the switching elements SW1 to SW4 via lines L4 to L7, respectively, and controls these switching elements SW1 to SW4. The parts A to D of the lines L4 to L7 drawn out from the control unit DR1 are extended to the parts A to D of the switching elements SW1 to SW4, respectively. Moreover, the control unit DR1 is connected to secondary synchronous rectification switches (parts indicated by E and F) of a rectifier circuit 135, which will be described later, and controls these switches.

The DC voltage supply unit 140 includes the rectifier circuit 135, a DC reactor Lch, and a capacitor Co, with the rectifier circuit 135 rectifying the output of the main transformer MT and converting it into a DC voltage. The DC voltage supply unit 140 supplies a desired DC voltage to a power supply ES2. The main transformer MT is a potential transformer that converts the high-frequency AC voltage on the primary side into a voltage suitable for the output.

The DC-to-DC converter circuit 105 has a high-voltage portion 150 to which a high voltage is applied. There is a line L1, between a power supply HV and the third switching element SW3, which becomes the high-voltage portion 150. The voltage across the high-voltage portion 150 is not limited to a particular voltage but, for example, ranges from 400 to 800 V. Additionally, the DC-to-DC converter circuit 105 includes a low-voltage portion 151 adjacent to the high-voltage portion 150, where the voltage becomes lower. Specifically, there is a line L2, between the power supply HV and a branching point DP3 (branched to the smoothing capacitor Ci), which becomes the low-voltage portion 151 where the voltage is low. There is a line L3, between the branching point DP1 and the main transformer MT, which becomes the low-voltage portion 151. The lines L4 to L7 that input a signal to the switching elements SW1 to SW4 become the low-voltage portion 151.

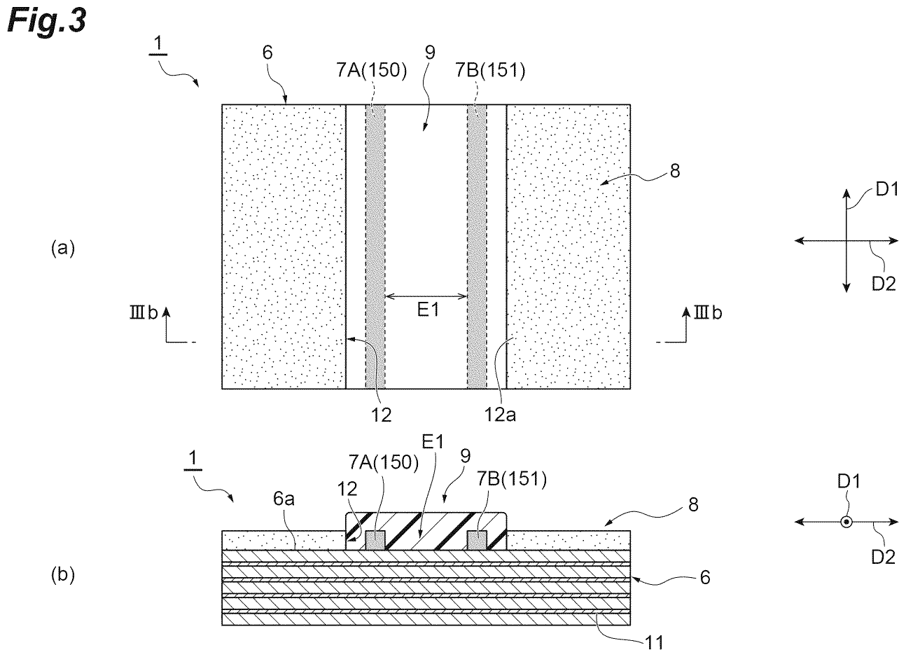

Referring to FIG. 3, the substrate structure 1 according to the present embodiment is now described. FIG. 3(a) is a plan view of the substrate structure 1. FIG. 3(b) is a cross-sectional view taken along the line IIIb-IIIb in FIG. 3(a). The substrate structure 1 is a structure applied or implemented near the high-voltage portion 150 and the low-voltage portion 151 of the electronic substrate 3 (refer to FIG. 1). As illustrated in FIG. 3, the substrate structure 1 includes a substrate 6, a pair of conductor patterns 7A and 7B, a resist layer 8, and a coating layer 9.

The substrate 6 is a flat base member on which electronic components not illustrated are mounted. The substrate 6 has a main surface 6a that is used as a mounting surface for respective electronic components. Moreover, in the following description, the direction perpendicular to the main surface 6a is referred to as the vertical direction, and the side where the main surface 6a is located is referred to as the “upper side”. However, the vertical direction herein is set for convenience and does not limit the orientation or posture of the power supply device 100 (refer to FIG. 1) during use. The substrate 6 includes a ceramic sheet and a conductive layer and is constructed by stacking them. The material of the substrate 6 is not limited to a particular one but, for example, glass epoxy, ceramic, or the like may be employed. The substrate 6 has a plurality of conductive layers 11 formed therein.

The conductor patterns 7A and 7B are formed on the main surface 6a of the substrate 6. The conductor patterns 7A and 7B extend in a predetermined direction and are spaced apart from each other. Moreover, the direction in which the conductor patterns 7A and 7B extend is referred to as an extending direction D1, and the direction in which the conductor patterns 7A and 7B are spaced apart is referred to as a width direction D2. In the present embodiment, the conductor patterns 7A and 7B extend linearly in the extending direction D1. The one conductor pattern 7A and the other conductor pattern 7B extend such that they are parallel to each other. The conductor patterns 7A and 7B are not limited to a particular one as long as they are made of conductive material, and may be made of, for example, Cu, tungsten, or the like.

Herein, the one conductor pattern 7A is a conductor pattern of the high-voltage portion 150 to which a high voltage is applied. The conductor pattern 7A is a pattern corresponding to the line L1 (refer to FIG. 2). The other conductor pattern 7B is a conductor pattern of the low-voltage portion 151 to which a low voltage is applied. The conductor pattern 7B is a pattern corresponding to any one of the lines L2, L3, and L4 to L7 (refer to FIG. 2) included in the low-voltage portion 151. In this way, the high-voltage portion 150 and the low-voltage portion 151 are arranged side by side in a state where there is a significant potential difference. The separation distance between the conductor pattern 7A and the conductor pattern 7B in the width direction D2 is not limited to a particular distance, but may be set in the range of 0.1 to 5 mm for miniaturization purposes.

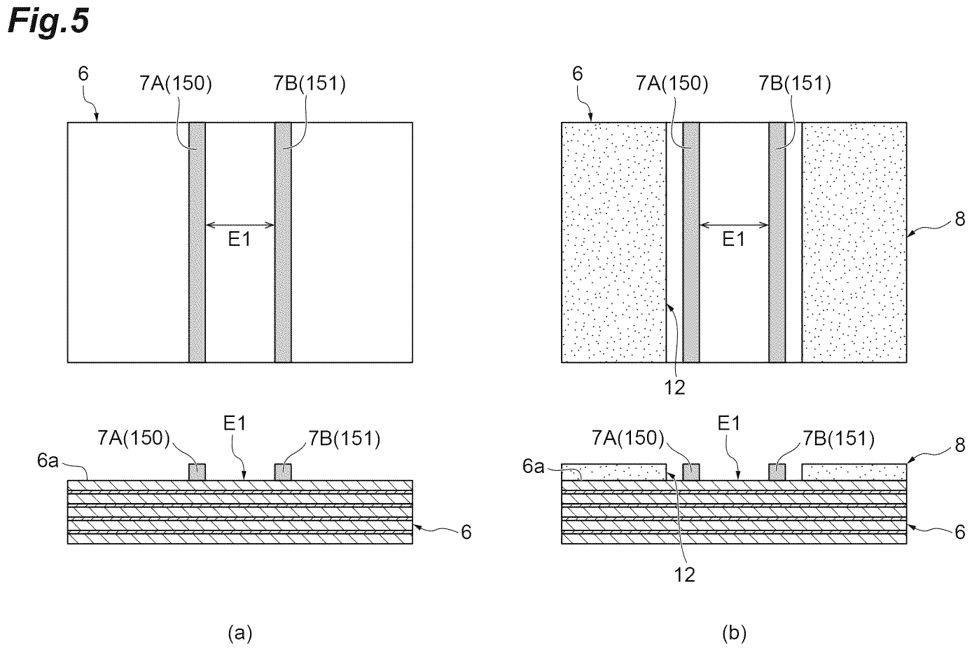

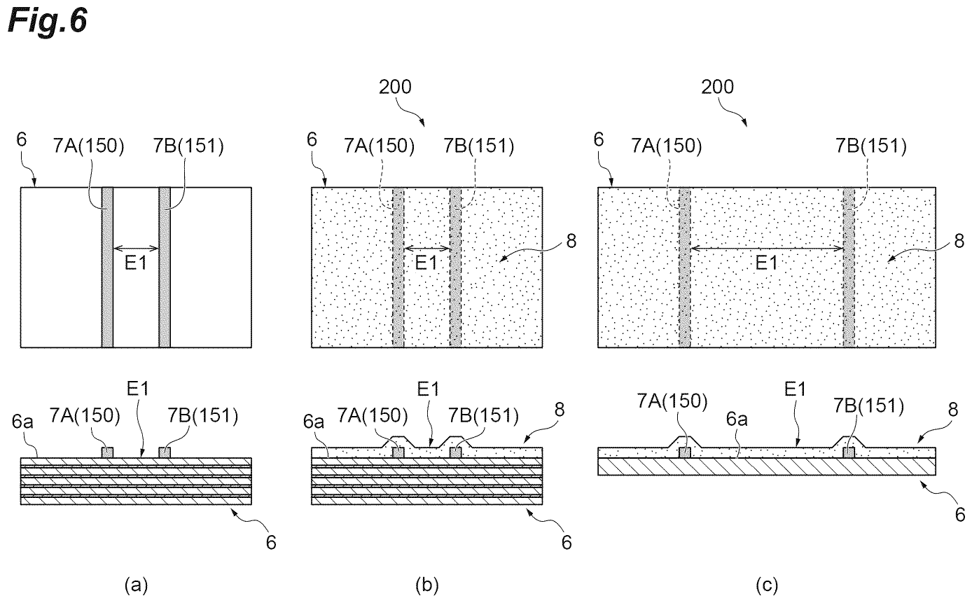

The region between the pair of conductor patterns 7A and 7B is referred to as “region E1”. The region E1 indicates a portion where the planar shape of the main surface 6a of the substrate 6 is continuous from the one conductor pattern 7A to the other conductor pattern 7B. For example, in a case where there is a slit (refer to FIGS. 5 and 6) that forms a depression with respect to the substrate 6 in the region E1, the planar shape of the main surface 6a is divided at the portion of the slit. Thus, by ensuring that the planar shape of the main surface 6a is continuous in the region E1, a configuration without slits or the like is achieved.

The resist layer 8 is a layer that covers the main surface 6a of the substrate 6. The resist layer 8 can prevent the accidental adhesion of solder or similar substances to the main surface 6a of the substrate 6. Although the material of the resist layer 8 is not limited to a particular one, for example, epoxy resin or similar materials may be employed. Additionally, the thickness of the resist layer 8 is not limited to a particular value, but may be in the range of 0 to 150 μm. The resist layer 8 has lower insulation properties than a coating layer 9 and does not meet a predetermined standard value. For example, the resist layer 8 has a thickness of less than 10 μm, which is the standard value for insulation.

The resist layer 8 has an opening 12 formed to be open to the region E1 and to the conductor patterns 7A and 7B. In the present embodiment, the opening 12 extends outwardly to a greater extent in the width direction D2 than the conductor patterns 7A and 7B. The opening 12 extends along the extending direction D1. In plan view, the opening 12 has an edge portion 12a extending linearly in a manner parallel to the conductor patterns 7A and 7B. In the opening 12, the resist layer 8 is not present in plan view. Thus, in the opening 12, the main surface 6a is not covered by the resist layer 8 and is exposed.

The coating layer 9 is a member that is formed in the opening 12 to cover the main surface 6a. Thus, in at least part of the region E1 between the pair of conductor patterns 7A and 7B, the coating layer 9 covers the substrate 6 while being in contact with it. In the present embodiment, the coating layer 9 covers the entire region E1 corresponding to the opening 12 and even parts of the substrate 6 outside the width direction D2 of the conductor patterns 7A and 7B, being in contact with the main surface 6a. Additionally, by covering the conductor patterns 7A and 7B, the coating layer 9 also contacts the upper and side surfaces of the conductor patterns 7A and 7B. The upper surface of the coating layer 9 is located at a higher position than the upper surface of resist layer 8. The coating layer 9 has higher insulation properties than the resist layer 8. The material of the coating layer 9 is not limited to a particular one as long as it is an insulating material, and for example, silicone, acrylic, or similar materials may be employed. The coating layer 9 has a thickness of 10 μm or more, which is the standard value for insulation. Additionally, the coating layer 9 has higher adhesiveness to the substrate 6 than the resist layer 8. The coating layer 9 has higher adhesion durability to the substrate 6 after endurance than the resist layer 8. Moreover, “after endurance” refers to after using the power supply device 100 in a high-temperature and high-humidity environment within an engine room for a predetermined period. For example, the adhesion or cohesion durability of the coating layer 9 to the substrate 6 is 0.1 MPa or more.

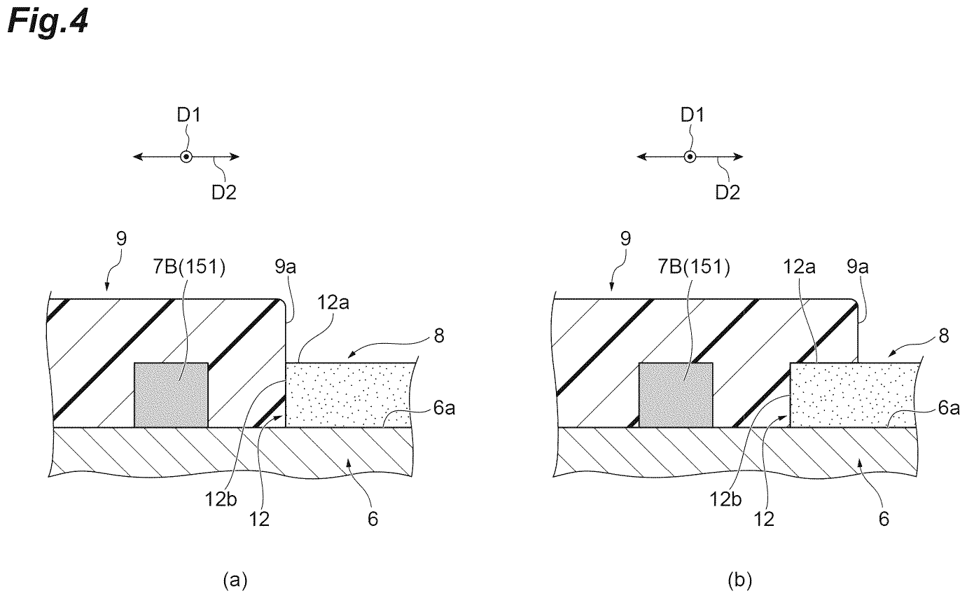

FIG. 4 is an enlarged view illustrating the structure near an end portion 9a of the coating layer 9 in the width direction D2. As illustrated in FIG. 4(a), the end portion 9a of the coating layer 9 may extend to the position of an inner peripheral surface 12b of the opening 12. As a result, the coating layer 9 is structured not to climb up to the resist layer 8 at the edge portion 12a of the opening 12. Additionally, as illustrated in FIG. 4(b), the end portion 9a of the coating layer 9 may extend further outward than the inner peripheral surface 12b of the opening 12 in the width direction D2. This arrangement allows the coating layer 9 to cover the resist layer 8 at the edge portion 12a of the opening 12.

The following describes a method of manufacturing the substrate structure 1 with reference to FIG. 5. Moreover, the upper parts of FIG. 5(a) and 5(b) illustrate plan views of the substrate structure 1, and the lower parts illustrate cross-sectional views of the substrate structure. As illustrated in FIG. 5(a), the conductor patterns 7A and 7B are formed on the main surface 6a of the substrate 6. Then, as illustrated in FIG. 5(b), the resist layer 8 is formed on the main surface 6a of the substrate 6. In this event, the opening 12 is formed in the resist layer 8. Then, as illustrated in FIG. 3, the coating layer 9 is formed by filling the opening 12 with a coating material.

The description is now given on the operation and effects of the substrate structure 1 and the power supply device 100 according to the present embodiment.

To begin with, a substrate structure 200 according to a first comparative example is described with reference to FIG. 6. As illustrated in FIG. 6(a) and 6(b), in the substrate structure 200 according to the first comparative example, the entire main surface 6a of the substrate 6 is covered with the resist layer 8. Herein, in the case where the power supply device is used in the vehicle's engine room, the electronic substrate is exposed to high temperature and humidity conditions. Under these conditions, there is a possibility that the resist layer 8 may peel off from the substrate 6. On the other hand, the pair of conductor patterns 7A and 7B with a significant voltage difference are formed on the substrate 6 so as to be lined up. The peeling of the resist layer 8 between the pair of conductor patterns 7A and 7B leads to a challenge that ionized metal moves along the surface of the substrate 6, which causes migration because the resist layer 8 is not a layer made of an insulating material. This challenge occurs similarly even if the region E1 is covered with a coating layer from above the resist layer 8. On the other hand, as illustrated in FIG. 6(c), increasing the separation distance between the conductor patterns 7A and 7B to suppress migration results in the challenge of increasing the size of the substrate structure 200.

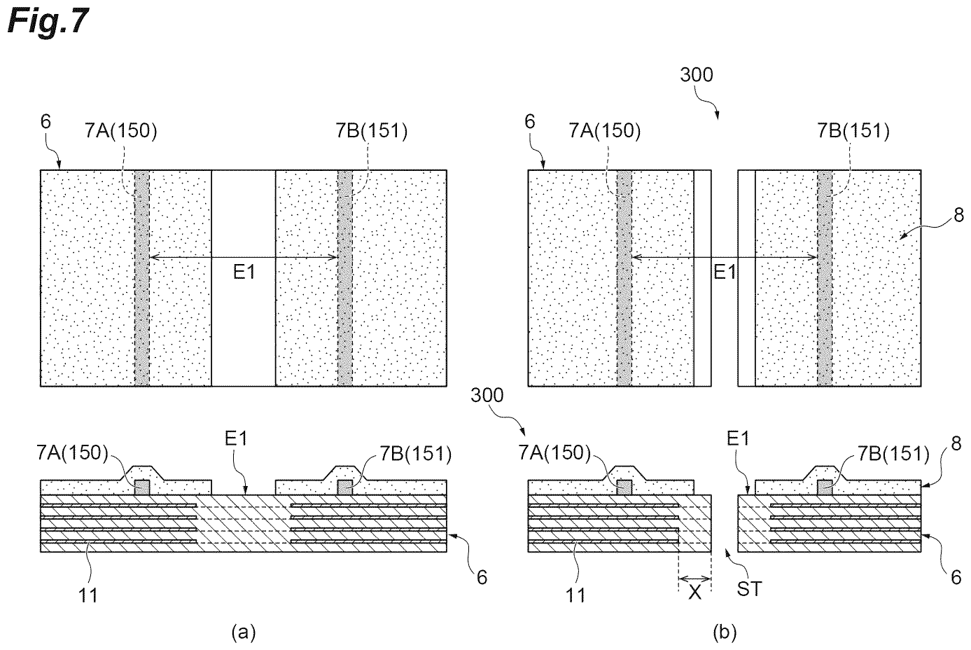

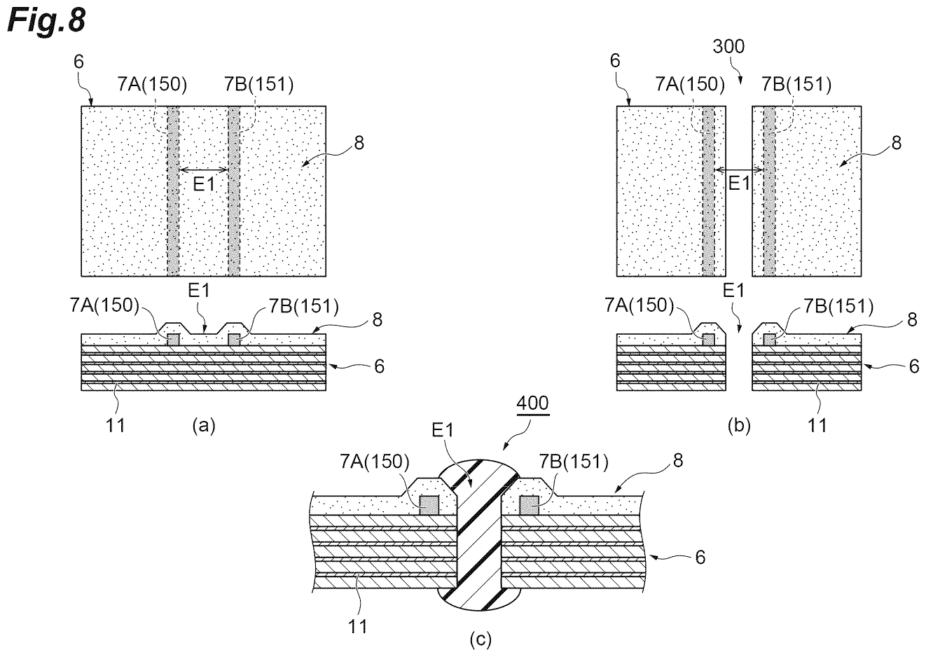

The following describes a substrate structure 300 according to a second comparative example with reference to FIGS. 7 and 8. As illustrated in FIGS. 7 and 8, the substrate structure 300 according to the second comparative example suppresses migration by providing a slit ST that penetrates the substrate 6 in the region E. The substrate 6 with increased distance between the conductor patterns 7A and 7B is prepared as illustrated in FIG. 7(a), and the slit ST is formed in the region E1 as illustrated in FIG. 7(b). In this arrangement, the slit ST is formed such that the insulation distance between the end portion of the conductive layer 11 in the substrate 6 and the inner surface of the slit ST is X. However, since the slit ST is formed by machining, this increases the processing cost. Furthermore, to ensure insulation distance, it is necessary to make the region E1 somewhat large. This leads to an increase in the size of the substrate. This leads to an increase in the size of the substrate. Additionally, in the case of applying high voltage, moisture or the like is likely to enter through a gap between the layers of the substrate 6 at the slit ST, potentially causing migration. For example, moisture is likely to enter through a gap between prepreg materials, which is between the layers of the substrate 6, potentially causing migration in the conductive layer 11, which is an intra-layer pattern.

To make the size of the substrate smaller, as illustrated in FIG. 8(a), a substrate with a shorter distance between the conductor patterns 7A and 7B is prepared, and as illustrated in FIG. 8(b), the slit ST is formed in the region E1. In this arrangement, the conductive layer 11 is exposed on the inner surface of the slit ST. In this case as well, machining of the slit ST is required, which increases the processing cost. Additionally, since the conductive layer 11 is exposed on the inner surface of the slit ST, corrosion of the conductive layer 11 and insulation failure due to moisture may occur. Furthermore, a challenge arises in that the insulation distance between layers (thickness direction) is insufficient. Moreover, it may be acceptable to employ a substrate structure 400 that forms the coating layer 9 by filling the slit ST with a resin material. However, compared to the aspect illustrated in FIG. 3, it is necessary to apply a resin material in consideration of viscosity and hardening properties so that the narrow slit ST can be filled. Moreover, in the structure illustrated in FIG. 7(b), a coating layer may also be formed on the slit ST.

In contrast, the substrate structure 1 according to the present embodiment has the pair of conductor patterns 7A and 7B formed on the main surface 6a of the substrate 6 and arranged spaced apart from each other. In addition, in at least part of the region E1 between the pair of conductor patterns 7A and 7B, the coating layer 9 having higher adhesiveness than the resist layer 8 covers the substrate 6 while being in contact with the substrate 6. According to this structure, even if the resist layer 8 peels off from the main surface 6a of the substrate 6, the high adhesiveness of the coating layer 9 in contact with the substrate 6 makes it possible to ensure insulation properties in the region E1 between the pair of conductor patterns 7A and 8B. Thus, it is possible to suppress migration between the pair of conductor patterns 7A and 7B. As described above, migration can be suppressed.

The resist layer 8 may be formed with the opening 12 that opens to at least part of the region E1 and to the conductor patterns 7A and 7B, and the coating layer 9 may be formed within the opening 12. In this case, a wide range including the vicinity of the conductor patterns 7A and 7B is protectable by the coating layer 9.

In the region E1 between the pair of conductor patterns 7A and 7B, the planar shape of the main surface 6a of the substrate 6 may be continuous from the one conductor pattern 7A to the other conductor pattern 7B. Even without forming the slit ST in the substrate 6, migration can be suppressed by the coating layer 9. Compared to the substrate structure 400 in FIG. 8(c), migration can be suppressed while keeping processing costs low.

The resist layer 8 may be formed with the opening 12 that opens to at least part of the region E1, and the coating layer 9 may cover the resist layer 8 at the edge portion 12a of the opening 12. In this case, it is possible to improve the adhesiveness at the boundary between the resist layer 8 and the coating layer 9.

The one conductor pattern 7A and the other conductor pattern 7B may extend parallel to each other. In this case, since the distance between the conductor patterns 7A and 7B remains constant, a similar insulation structure is applicable in the extending direction D1 of the conductor patterns 7A and 7B.

The power supply device 100 according to the present embodiment may have the substrate structure 1 described above.

The power supply device 100 allows similar operations and effects to be achieved as the substrate structure 1 described above.

The present invention is not limited to the embodiments described above.

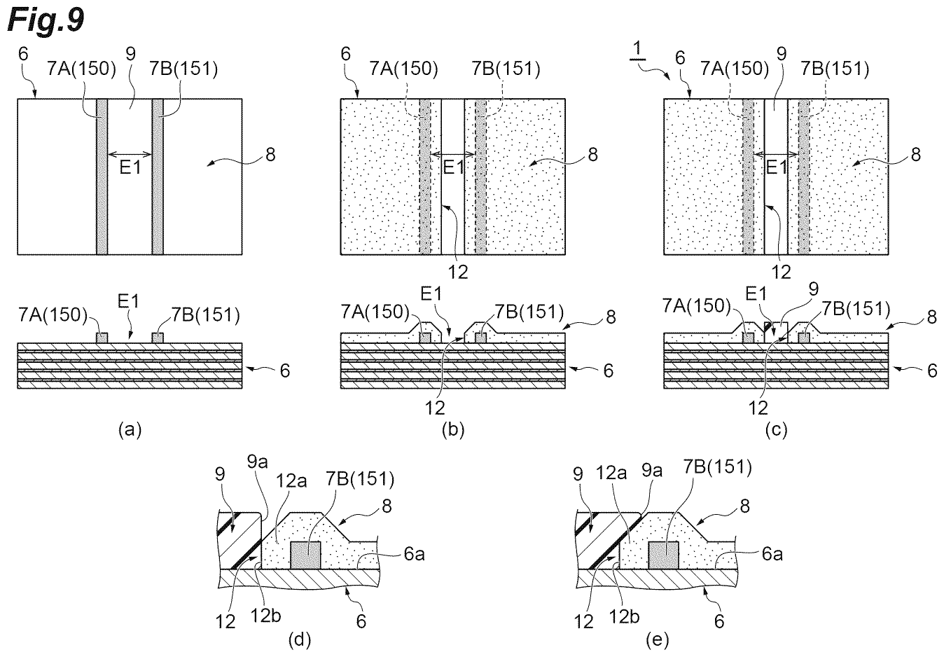

For example, a structure illustrated in FIG. 9 may be employed. As illustrated in FIG. 9(c), the resist layer 8 covers the conductor patterns 7A and 7B, and the resist layer 8 is formed with the opening 12 that opens to at least part of the region E1, and the coating layer 9 may be formed in the opening 12. In this case, it is possible to reduce or save the amount of the coating layer 9 compared to the case where the conductor patterns 7A and 7B are covered with the coating layer 9.

Moreover, during manufacturing, the conductor patterns 7A and 7B are formed on the main surface 6a of the substrate 6, as illustrated in FIG. 9(a). Subsequently, as illustrated in FIG. 9(b), the resist layer 8 is formed on the main surface 6a of the substrate 6 and on the conductor patterns 7A and 7B. In this event, the opening 12 is formed in the resist layer 8. Then, as illustrated in FIG. 9(c), the coating layer 9 is formed by filling the opening 12 with a coating material.

FIG. 9(d) and 9(e) are enlarged views illustrating the structure near the end portion 9a of the coating layer 9. As illustrated in FIG. 9(d), the end portion 9a of the coating layer 9 may extend to the position of the inner peripheral surface 12b of the opening 12. As a result, the coating layer 9 is structured not to climb up to the resist layer 8 at the edge portion 12a of the opening 12. Further, as illustrated in FIG. 9(e), the end portion 9a of the coating layer 9 may extend closer to the conductor pattern 7B than the inner peripheral surface 12b of the opening 12. This arrangement allows the coating layer 9 to cover the resist layer 8 at the edge portion 12a of the opening 12.

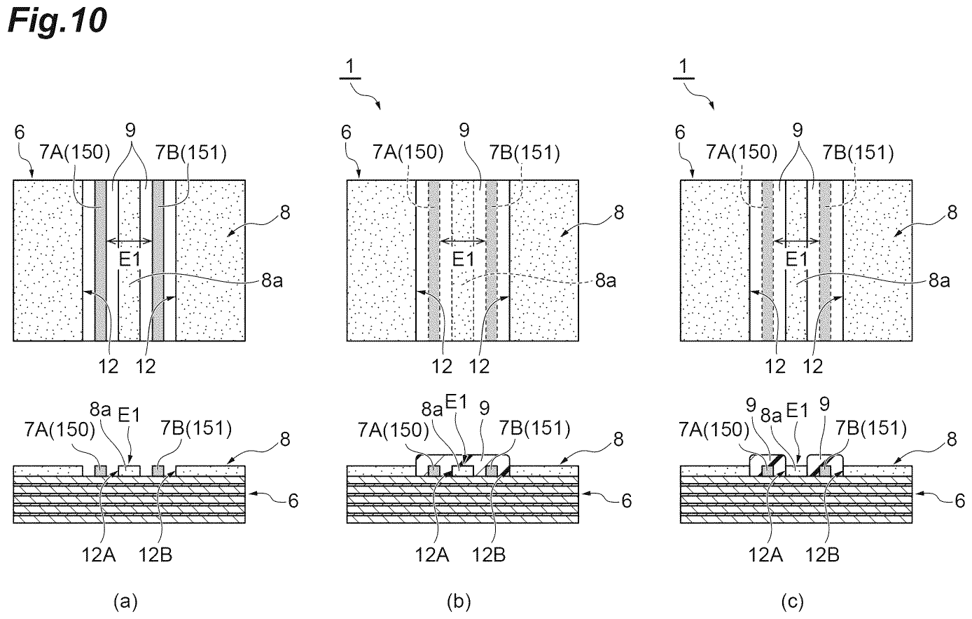

There may be employed a structure illustrated in FIG. 10. As illustrated in FIG. 10(b) and 10(c), the resist layer 8 is formed with a first opening 12A and a second opening 12B, with the first opening 12A being open at a position on the side of the one conductor pattern 7A in the region E1, and with the second opening 12B being open at a position on the side of the other conductor pattern 7B in the region E1. The resist layer 8 remains between the first opening 12A and the second opening 12B. Moreover, in FIG. 10, the portion of the resist layer 8 that remains between the openings 12A and 12B is illustrated as a remaining portion 8a. The coating layer 9 may be formed in the first opening 12A and the second opening 12B. As illustrated in FIG. 10(a), the resist layer 8 in which the openings 12A and 12B are formed is created on the substrate 6. In contrast, in FIG. 10(b), the coating layer 9 is formed to collectively cover the openings 12A and 12B. In FIG. 10(c), the coating layer 9 is formed individually for the respective openings 12A and 12B. In this case, allowing the resist layer 8 to remain between the conductor patterns 7A and 7B makes it possible to prevent the adhesion of solder or the like to the main surface 6a of the substrate 6.

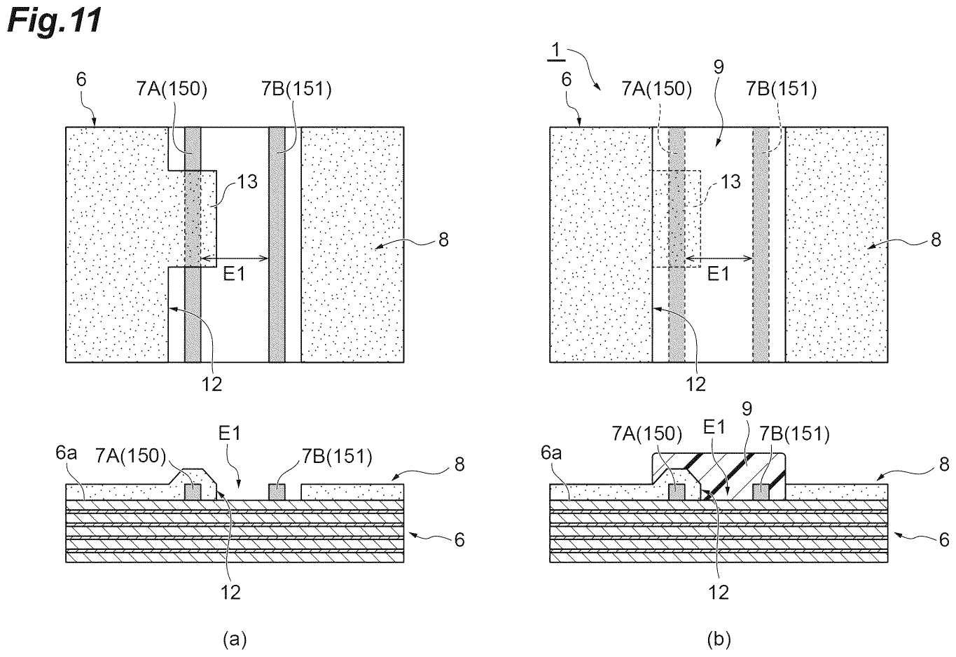

There may be employed a structure illustrated in FIG. 11. As illustrated in FIG. 11(b), the resist layer 8 may cover a portion of the conductor pattern 7A. The opening 12 is provided for the region E1 and the conductor patterns 7A and 7B. The portion of the conductor pattern 7A is covered by a cover portion 13 of the resist layer 8. As illustrated in FIG. 11(a), the opening 12 is formed in the substrate 6, and the resist layer 8 having the cover portion 13 is formed. On the other hand, as illustrated in FIG. 11(b), the coating layer 9 is formed on the opening 12 and the cover portion 13.

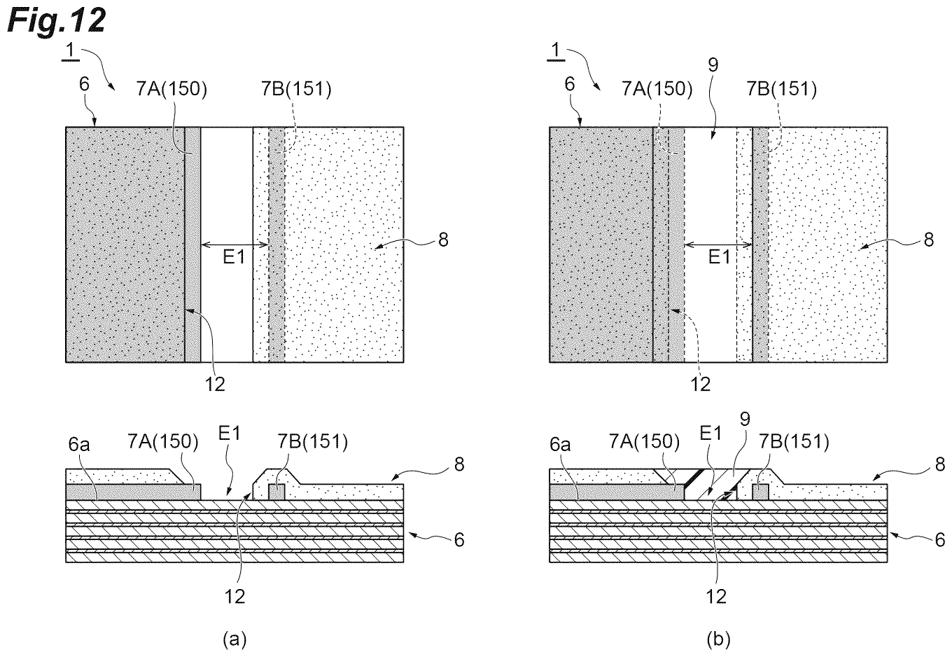

There may be employed a structure illustrated in FIG. 12. As illustrated in FIG. 12(b), the one conductor pattern 7A is not a linear pattern but a flat pattern that spreads out in a planar manner. The resist layer 8 is formed to cover the planar conductor pattern 7A and the linear conductor pattern 7B. The opening 12 is provided in the region E1 and near the end portion in the width direction of the conductor pattern 7A. As illustrated in FIG. 12(a), the planar conductor pattern 7A and the linear conductor pattern 7B are formed on the substrate 6, and the resist layer 8 having the opening 12 is formed. On the other hand, as illustrated in FIG. 12(b), the coating layer 9 is formed on the opening 12.

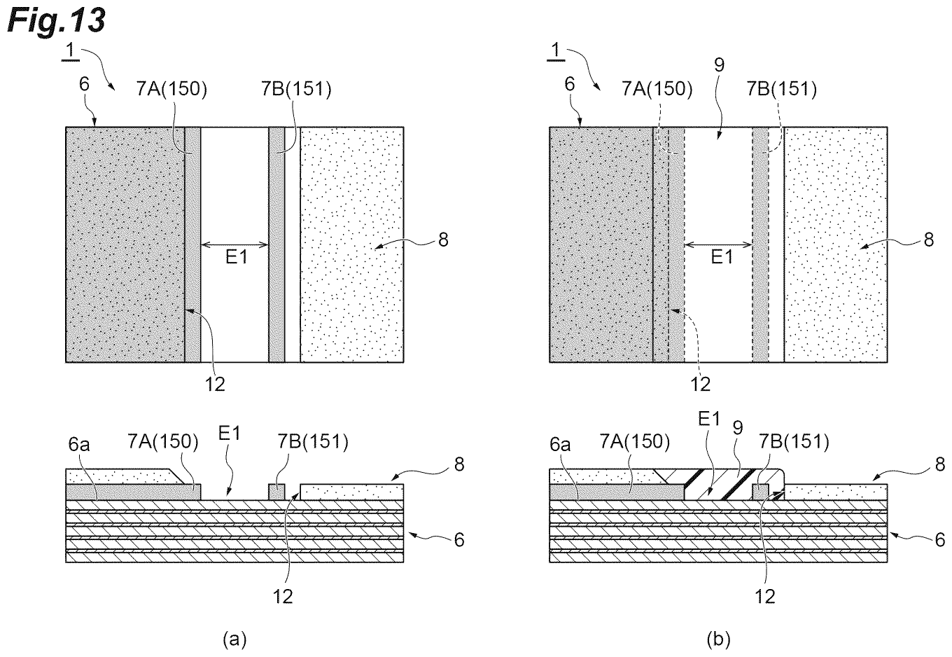

There may be employed a structure illustrated in FIG. 13. The structure illustrated in FIG. 13 is similar to that illustrated in FIG. 12, except that the other conductor pattern 7B is not covered with the resist layer 8. As illustrated in FIG. 13(b), the opening 12 is provided for the other conductor pattern 7B. This arrangement allows the coating layer 9 to cover the other conductor pattern 7B and the surrounding main surface 6a.

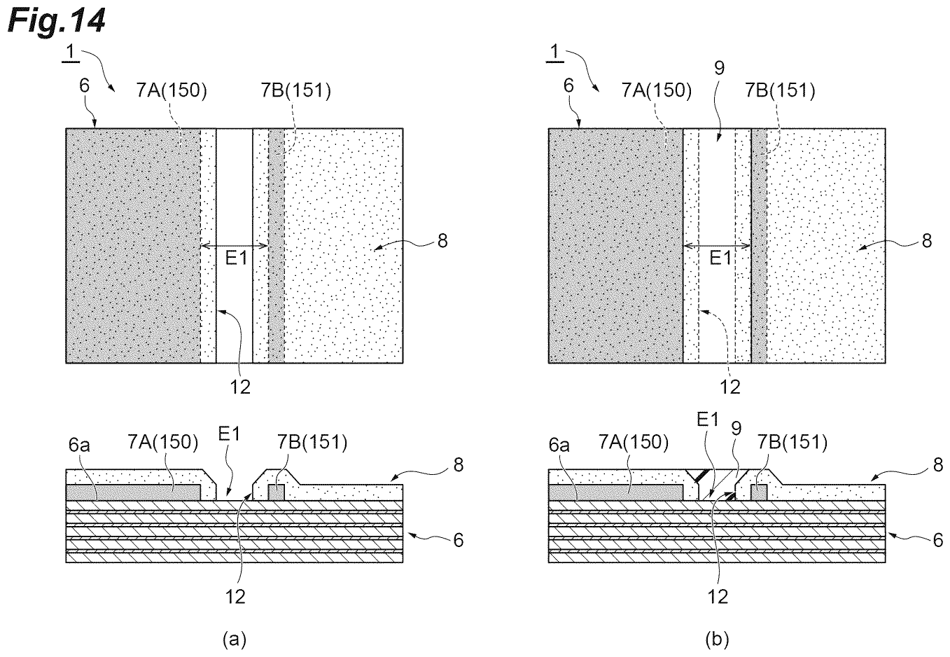

There may be employed a structure illustrated in FIG. 14. The structure illustrated in FIG. 14 is similar to that illustrated in FIG. 12, except that the end portion of the one conductor pattern 7A is also covered with the resist layer 8. As illustrated in FIG. 14(b), the opening 12 is provided on a part of the main surface 6a of the region E1. The resist layer 8 covers the entire planar conductor pattern 7A and the entire linear conductor pattern 7B.

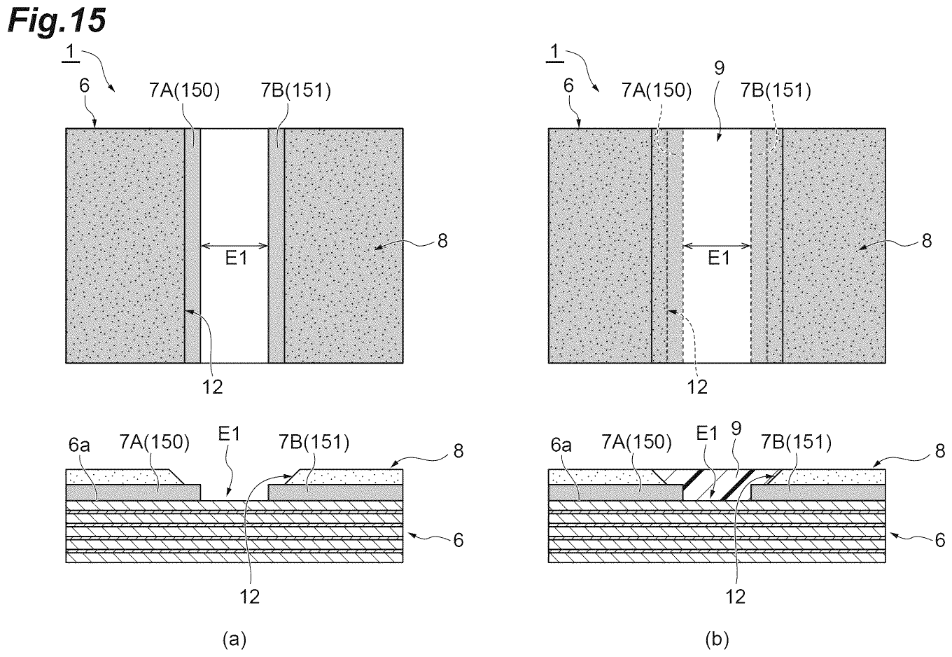

There may be employed a structure illustrated in FIG. 15. As illustrated in FIG. 15(b), both the conductor patterns 7A and 7B are not linear patterns but flat patterns spreading in a plane. The resist layer 8 is formed to cover the planar conductor patterns 7A and 7B. The opening 12 is provided in the region E1 and near the end portions in the width direction of the conductor patterns 7A and 7B. As illustrated in FIG. 15(a), the planar conductor patterns 7A and 7B are formed on the substrate 6, and the resist layer 8 having the opening 12 is formed. On the other hand, as illustrated in FIG. 15(b), the coating layer 9 is formed on the opening 12.

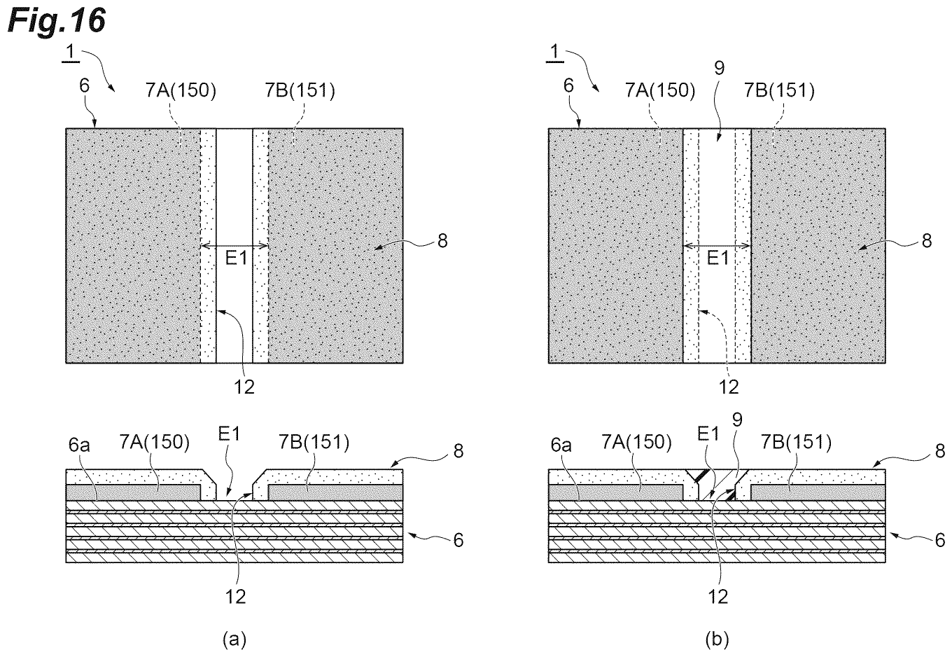

There may be employed a structure illustrated in FIG. 16. The structure illustrated in FIG. 16 is similar to that illustrated in FIG. 15, except that the end portions of the conductor patterns 7A and 7B on both sides are covered with the resist layer 8. As illustrated in FIG. 15(b), the opening 12 is provided on a part of the main surface 6a of the region E1. The resist layer 8 covers the entire planar conductor patterns 7A and 7B.

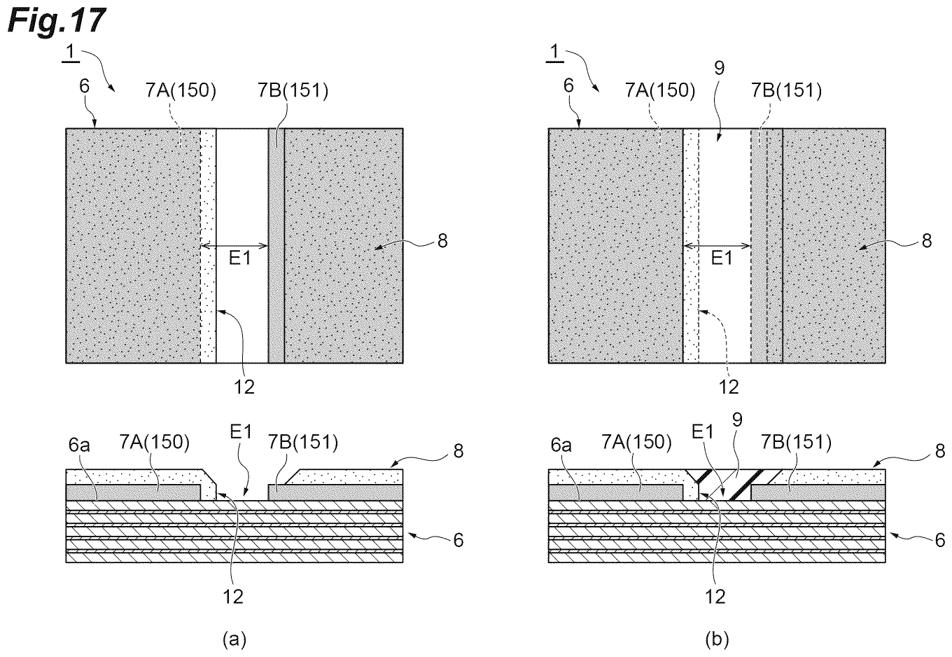

There may be employed a structure illustrated in FIG. 17. The structure illustrated in FIG. 17 is similar to that illustrated in FIG. 12, except that only the end portion of one conductor pattern 7A is covered with the resist layer 8. As illustrated in FIG. 17(b), the opening 12 is provided on a part of the main surface 6a of the region E1 and near the end portion of the other conductor pattern 7B. The resist layer 8 covers the entire planar conductor pattern 7A and the portions of the planar conductor pattern 7B other than its end portion.

In the above-described embodiments, the case where the power supply device is placed in the engine room or the like of an automobile has been described. However, the installation location of the power supply device is not limited to a particular one and may be placed inside the vehicle cabin or the like. Furthermore, while the device employing the substrate structure has been exemplified with a power supply device equipped with a DC-to-DC converter, it is not limited to a particular configuration and may be employed in devices such as inverters and chargers.

### [First Aspect]

A substrate structure including:
a substrate;
a pair of conductor patterns formed on a main surface of the substrate and arranged spaced apart from each other; and
a resist layer covering the main surface of the substrate, wherein
in at least part of a region between the pair of conductor patterns, a coating layer having higher adhesiveness than the resist layer covers the substrate, with the coating layer being in contact with the substrate.

### [Second Aspect]

The substrate structure according to the first aspect, wherein the resist layer is formed with an opening that opens to at least part of the region and to the conductor pattern, with the coating layer being formed in the opening.

### [Third Aspect]

The substrate structure according to the first aspect, wherein the resist layer covers the conductor pattern, and
the resist layer is formed with an opening that opens to at least part of the region, with the coating layer being formed in the opening.

### [Fourth Aspect]

The substrate structure according to the first or second aspect, wherein
the resist layer is formed with
a first opening that opens at a position on one of the conductor patterns in the region and
a second opening that opens at a position on the other of the conductor patterns in the region,
the resist layer remains between the first opening and the second opening, and
the coating layer is formed in the first opening and the second opening.

### [Fifth Aspect]

The substrate structure according to any one of the first to fourth aspects, wherein the main surface of the substrate has a planar shape being continuous from one of the conductor patterns to the other of the conductor patterns in the region between the pair of the conductor patterns.

### [Sixth Aspect]

The substrate structure according to any one of the first to fifth aspects, wherein the resist layer is formed with an opening that opens to at least part of the region, and the coating layer covers the resist layer at an edge portion of the opening.

### [Seventh Aspect]

The substrate structure according to any one of the first to sixth aspects, wherein the one of the conductor patterns and the other of the conductor patterns extend parallel to each other.

### [Eighth Aspect]

A power supply device with the substrate structure according to any one of the first to seventh aspects.

### REFERENCE SIGNS LIST

1 SUBSTRATE STRUCTURE
6 SUBSTRATE
6a MAIN SURFACE
7A, 7B CONDUCTOR PATTERN
8 RESIST LAYER
9 COATING LAYER
12 OPENING
12A FIRST OPENING
12B SECOND OPENING
100 POWER SUPPLY DEVICE

1. A substrate structure comprising:
a substrate;
a pair of conductor patterns formed on a main surface of the substrate and arranged spaced apart from each other; and
a resist layer covering the main surface of the substrate, wherein
in at least part of a region between the pair of conductor patterns, a coating layer having higher adhesiveness than the resist layer covers the substrate, with the coating layer being in contact with the substrate.

2. The substrate structure according to claim 1, wherein the resist layer is formed with an opening that opens to at least part of the region and to the conductor pattern, with the coating layer being formed in the opening.

3. The substrate structure according to claim 1, wherein the resist layer covers the conductor pattern, and
the resist layer is formed with an opening that opens to at least part of the region, with the coating layer being formed in the opening.

4. The substrate structure according to claim 1, wherein
the resist layer is formed with
a first opening that opens at a position on one of the conductor patterns in the region and
a second opening that opens at a position on the other of the conductor patterns in the region,
the resist layer remains between the first opening and the second opening, and
the coating layer is formed in the first opening and the second opening.

5. The substrate structure according to claim 1, wherein the main surface of the substrate has a planar shape being continuous from one of the conductor patterns to the other of the conductor patterns in the region between the pair of the conductor patterns.

6. The substrate structure according to claim 1, wherein the resist layer is formed with an opening that opens to at least part of the region, and the coating layer covers the resist layer at an edge portion of the opening.

7. The substrate structure according to claim 1, wherein the one of the conductor patterns and the other of the conductor patterns extend parallel to each other.

8. A power supply device with the substrate structure according to claim 1.
